(19) United States
(12) Patent Application Publication
(10) Pub. No.: US 2022/0399903 A1
(43) Pub. Date: Dec. 15, 2022

(54) DECODING METHOD ADOPTING ALGORITHM WITH WEIGHT-BASED ADJUSTED PARAMETERS AND DECODING SYSTEM

(71) Applicant: REALTEK SEMICONDUCTOR CORP., Hsinchu (TW)

(72) Inventors: LIANG-WEI HUANG, HSINCHU (TW); YUN-CHIH TSAI, HSINCHU (TW)

(21) Appl. No.: 17/835,325

(22) Filed: Jun. 8, 2022

(30) Foreign Application Priority Data
Jun. 11, 2021 (TW) 110121280

(51) Int. Cl. H03M 13/11; H03M 13/45; H03M 13/51

(52) U.S. Cl. CPC H03M 13/1125; H03M 13/1117; H03M 13/458; H03M 13/51

(57) ABSTRACT

A decoding method adopting an algorithm with weight-based adjusted parameters and a decoding system are provided. The decoding method is applied to a decoder. M×N low density parity check codes (LDPC codes) having N variable nodes and M check nodes are generated from input signals. In the decoding method, information of the variable nodes and the check nodes is initialized. The information passed from the variable nodes to the check nodes is formed after multiple iterations. After excluding a connection to be calculated, a product of the remaining connections between the variable nodes and the check nodes is calculated. Next, an estimated first minimum or an estimated second minimum can be calculated with multi-dimensional parameters. The information passed from the check nodes to the variable nodes can be updated for making a decision.

### CROSS-REFERENCE TO RELATED PATENT APPLICATION

This application claims the benefit of priority to Taiwan Patent Application No. 110121280, filed on Jun. 11, 2021. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a decoding technology, and more particularly to a decoding method that adjusts parameters of an algorithm in a decoder based on weights for performance enhancement and a decoding system.

### BACKGROUND OF THE DISCLOSURE

A low density parity check code (LDPC code) is an error correcting code used to correct an error occurred during a signal transmission process, which allows the signal transmission to be very close to a theoretical maximum performance (the Shannon limit). The Shannon limit refers to a maximum transmission rate under a specified noise standard. Therefore, the LDPC code has currently become the most popular error correcting code. The low density parity check code can be used in various systems that require decoding and encoding operations. A system that uses the low density parity check code can be, for example, an IEEE802.11n standard wireless local area network, a satellite television system, and an IEEE802.3an standard system with 10 Gbps Ethernet communication over unshielded twisted pair.

The best decoding performance of the low density parity check code is a soft decoding process that uses the belief propagation (BP) recursion (which can be a sum-product (SP) algorithm). Since hardware complexity of the conventional sum-product algorithm is too high, a simplified version of the sum-product algorithm (such as a min-sum (MS) algorithm) has been developed. However, even though the hardware complexity of the min-sum algorithm can be greatly reduced, a serious problem of performance degradation also occurs. Accordingly, based on the min-sum algorithm, a normalized min-sum (NMS) algorithm and an offset min-sum (OMS) algorithm that improve the problem of performance degradation have been developed. The NMS algorithm and the OMS algorithm currently have attracted much attention given that these algorithms preserve the performance of the above-mentioned sum-product algorithm with only a small increase in hardware complexity.

While both of the normalized min-sum algorithm and the offset min-sum algorithm can provide a decoder framework with lower complexity, the min-sum algorithm is still required to perform searching of a first minimum (min1) and a second minimum (min2) while performing a check node update. The complexity of the normalized min-sum algorithm and the offset min-sum algorithm depends on a check node degree that is generally based on a number of variable nodes covered by a check equation.

Taking a 10 Gbps Ethernet network system as an example, the check node degree of a LDPC decoder framework is 32. That is, every time the check node update is performed, these 32 variable nodes are required to obtain the first minimum (min1) and the second minimum (min2). This calculation limits a clock rate, a latency, a hardware area, an iteration number, and performance of the decoder.

To a processor, the loading of searching for the first minimum is relatively lower than that of searching for the second minimum since a sorting process is required when searching for the second minimum. Further, the greater the number of the variable nodes is, the greater a calculation amount is. Therefore, to reduce the loading of searching for the second minimum, a single-min algorithm (SMA) has been developed. The framework of the single-min algorithm is to modify the behavior of the check node update in the min-sum algorithm. The single-min algorithm is to search only for the first minimum, but not for the second minimum. The single-min algorithm estimates the second minimum instead. In other words, after the second minimum is estimated, an estimated second minimum (min2^{est}) is obtained. The estimated second minimum is, for example, a scrambling second minimum.

When the estimated second minimum (min2^{est}) is appropriately calculated, an error floor of the low density parity check code can be mitigated. The error floor refers to a phenomenon in which a falling trend of an error rate of the low density parity check code (LDPC code) is slowed down due to a trapping set or an absorbing set if the error rate of the LDPC code is low enough. For example, in the IEEE802.3an standard system, the error rate usually occurs around BER=10⁻¹⁰ and FER=10⁻⁸. The mitigated error floor has a bad effect on the system However, when noises are appropriately added to the single-min algorithm, opportunities to escape the trapping set are increased for the LDPC code, such that the single-min algorithm is capable of reducing the effect of the error floor.

### SUMMARY OF THE DISCLOSURE

The present disclosure is related to a decoding method adopting an algorithm with weight-based adjusted parameters and a decoding system. In addition to having the advantage of providing a conventional single-min algorithm with improved decoding performance, the decoding method uses a modified single-min-sum algorithm (modified SMAMSA) that modifies two-dimensional variables of the single-min-sum algorithm to three-dimensional variables by adjusting weights. The modified SMAMSA is able to increase a range of use and cooperate with more modulation methods, so as to acquire a wider range of fixed points of a decoder.

In an aspect of the present disclosure, the decoding method adopting an algorithm with weight-based adjusted parameters is applied to a decoder. Input signals form M×N low density parity check codes (LDPC codes). The LDPC codes include multiple (N) variable nodes and multiple (M) check nodes. In the decoding method, information of the variable nodes and the check nodes is initialized, and the information that the variable nodes provide to the check nodes is formed after multiple iterations. After excluding the connection to be calculated, a sum of the remaining connections among the variable nodes and the check nodes is calculated. The information of each of the variable nodes can be updated according to the information of the check nodes connected thereto. Further, the information that each check node provides to the variable nodes is formed after multiple iterations. After excluding the connection to be calculated, a product of the remaining connections among the variable nodes and the check nodes is calculated. The information of each of the check nodes can be updated according to the information of the variable nodes connected thereto. Afterwards, a dot product is calculated according to an estimated first minimum or an estimated second minimum. The dot product can be used to obtain the information that the check nodes provide to the variable nodes for making a decision.

In the process of obtaining the estimated first minimum and the estimated second minimum, a minimum of the updated variable nodes is searched for acquiring a first minimum. Data accompanied with the first minimum can be used to obtain a false second minimum. A first parameter (α) is multiplied by the first minimum for obtaining the estimated first minimum. A second parameter (β) is multiplied by the first minimum, and is added with a result of a third parameter (γ) multiplied by the false second minimum for acquiring the estimated second minimum.

The first parameter (α), the second parameter (β) and the third parameter (γ) satisfy a relational expression: (β+γ)≥α. A related equation is shown below, in which “N” denotes number of the variable nodes; “M” denotes number of the check nodes; “n” denotes a number of the variable node; “m” denotes a number of the check node; “c_{m,n}⁽ⁱ⁾” denotes information that the m-numbered check node sends to the n-numbered variable node; “n′” denotes a number of the remaining variable node(s) with exclusion of the connection to be calculated; “v_{n′,m}⁽ⁱ⁾” denotes information that the n′-numbered variable node(s) sends to the m-numbered check node after excluding the connection to be calculated, i.e., v2c information; a sign function “sign( )” is used to return the value “0”, “1” or “−1” according to the value “0”, “a positive number” or “a negative number” in the sign function; “min1” is a first minimum;

$$“ {min}_{{n}^{′} ∈ {N}_{m}} ( ) ”$$

a function used to acquire a minimum; “min1^{est}” is an estimated first minimum; “min2^{est}” is an estimated second minimum; and “min2′″” denotes a false second minimum.

$$For m ∈ \{ 1 , … M \} and n ∈ {N}_{m} ;$$

$${c}_{m , n}^{( i )} = ( {\prod }_{{n}^{′} ∈ {N}_{m ∖ n}} sign ( {v}_{{n}^{′} , m}^{( i )} ) ) \cdot \{ \begin{matrix}min {1}^{est} , & when “ n ” of {c}_{m , n}^{i} is not “ n ” where minimum v 2 c is located ; \\ min {2}^{est} , & others ;\end{matrix}$$

$$min 1 = {min}_{{n}^{′} ∈ {N}_{m}} ( \vert {v}_{{n}^{′} , m}^{( i )} \vert ) ;$$

$$min {1}^{est} = α \cdot min 1 ;$$

$$min {2}^{est} = β \cdot min 1 + γ \cdot min {2}^{′′′} .$$

Preferably, the estimated first minimum or the estimated second minimum is determined according to a determination of whether or not the number of the variable node in the information that one of the check nodes provides to the variable is the position of the information that the smallest variable node provides to the check node.

Further, the intrinsic information of the variable node is summed up with the information that the check node provides to the multiple variable nodes and is updated via a connection between the check node and the other variable nodes so as to obtain the information of the variable node for making the decision.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram depicting a circuit framework of a decoding system according to one embodiment of the present disclosure;

FIG. 2 is a schematic diagram exemplarily showing a Tanner graph that illustrates a decoding process with a low density parity check code;

FIG. 3 is a schematic diagram exemplarily showing a Tanner graph that illustrates a sum calculation during the decoding process with the low density parity check code;

FIG. 4 is a schematic diagram exemplarily showing a Tanner graph that illustrates a product calculation during the decoding process with the low density parity check code;

FIG. 5 to FIG. 8 show block diagrams of logic circuits that are used to calculate a first minimum and a false second minimum according to embodiments of the present disclosure;

FIG. 9 is a schematic block diagram of logic circuits that implement a modified SMAMSA according to one embodiment of the present disclosure; and

FIG. 10 is a flow chart describing a decoding method adopting an algorithm with weight-based adjusted parameters according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

The present disclosure is related to a decoding method adopting an algorithm with weight-based adjusted parameters and a decoding system. A modified single-min-sum algorithm (hereinafter referred to as “modified SMAMSA”) is provided. To improve performance of calculation, compared with conventional algorithms, the modified SMAMSA adopts variables with more dimensions. Furthermore, for the modified SMAMSA, the range of application is expanded, and lower error rates, reduced complexity of hardware, and efficient power consumption can also be achieved.

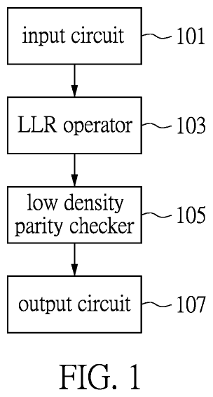

Reference is made to FIG. 1, which is a schematic diagram of a framework of the decoding system that implements the decoding method adopting an algorithm with weight-based adjusted parameters according to one embodiment of the present disclosure. In a signal transmission process of a communication system that uses the decoding system, to check whether or not the reliability of signal transmission of a transmission medium is reduced when data is damaged due to interference, additional information such as an error correction code (e.g., an LDPC code) can be used and be added into signals to be transmitted. The error correction code allows a receiving end to infer the correct information based on the received information, so as to restore the damaged data.

The decoding system includes a decoder disposed at the receiving end. The decoder receives signals via an input circuit 101. The signals are, for example, communication signals. After initializing the communication signals, the signals are inputted to a log-likelihood ratio operator 103, and the LLR operator 103 provides a log-likelihood ratio. Therefore, the decoding system can achieve a lower error rate and higher performance. Furthermore, a decode scaling can be used to control the log-likelihood ratio (LLR), so as to provide a correct log-likelihood ratio to a low density parity checker (LDPC) 105. In a decoding process, multiple updates and iterations can be performed according to connection relationships among check nodes and variable nodes. Lastly, the content of the signals can be verified based on a probability, and the decoded signals are outputted via an output circuit 107.

To explain the technical features of the decoding method adopting an algorithm with weight-based adjusted parameters and the decoding system according to certain embodiments of the present disclosure, the differences between the conventional single minimum algorithm and the min-sum algorithm will be described. An exemplary decoding process of the min-sum algorithm is as follows.

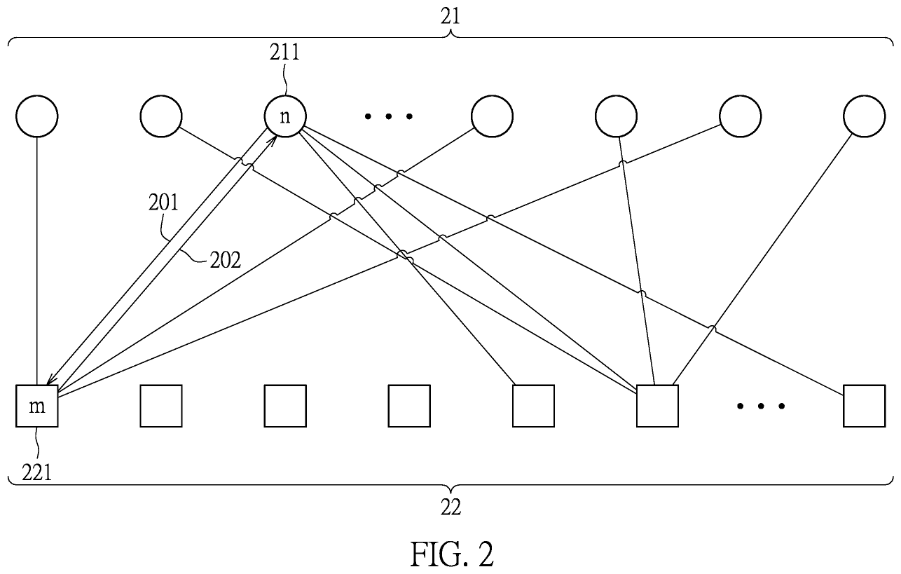

According to the various algorithms provided in different phases in the present disclosure (such as the modified SMAMSA), the algorithms can be applied to a decoder. In the min-sum algorithm, M×N low density parity check codes including N variable nodes and M check nodes are provided. It should be noted that the complexity of computation can be determined according to a degree of the check nodes, or a quantity of the variable nodes included in a check equation. Reference is made to FIG. 2, which is a schematic diagram depicting an exemplary example of a Tanner graph used to illustrate a decoding process with the low density parity check codes.

In FIG. 2, N variable nodes 21 and M check nodes 22 are shown. The decoding process of a decoder is based on a concept of message passing, e.g., probabilities calculated at each of the variable nodes 21 and the check nodes 22 being transmitted to each other. In the diagram, the probability that a specific variable node (e.g., an n^{th} variable node 211) transmits a message to one of the check nodes (e.g., an m^{th} check node 221) is calculated. With exclusion of the connection between the n^{th} variable node 211 and the m^{th} check node 221, the probability is determined based on the connections between the n^{th} variable node 211 and the other check nodes.

In the decoding equation with the low density parity check codes, “n” denotes a number of the variable node, “m” denotes a number of the check node, “Nₘ” denotes all of the variable nodes (N) 21 that participate in the current (m^{th}) check equation, and “M” denotes all of the check equations of the check nodes (M) 22 that participate in the current (n^{th}) variable node.

FIG. 2 also shows the multiple connections between the multiple variable nodes 21 and the multiple check nodes 22. These connections denote a decoding process with the low density parity check codes. In the decoding process, the information is transmitted to each other after the probabilities of the two types of the nodes are calculated. Here, the connection between the n^{th} variable node 211 and the m^{th} check node 221 is taken as an example. During an initialization process, intrinsic information (such as a log likelihood ratio (LLR) of a decoder) is written into the multiple variable nodes 21. It should be noted that the log likelihood ratio is used to indicate that a value of the variable node is close to 0 or 1. “i=k” denotes a k^{th} iteration in a LDCP decoding process. “v_{n,m}^{(i=k)}” denotes v2c information 201 that the n^{th} variable node 211 provides to the m^{th} check node 221 in the k^{th} iteration, in which “v2c” denotes the information that the variable node provides to the check node. “c_{m,n}^{(i=k)}” denotes c2v information 202 that the m^{th} check node 221 provides to the n^{th} variable node 211 in the k^{th} iteration. “c2v” denotes the information that the check node provides to the variable node. “In” denotes intrinsic information of the n^{th} variable node, and the intrinsic information refers to original information of when the nodes enter the system. “α” indicates a normalization factor. For example, in a min-sum algorithm (MS), “α=1”. In a normalized min-sum algorithm (NMS), “α≠1”.

The calculation steps of the min-sum algorithm are described as follows.

In an initialization stage, the intrinsic information is one-by-one written into the multiple variable nodes. For the check nodes, “i=0” denotes an initial state before an iteration (a 0^{th} iteration) is performed. In equation 1, “c_{m,n}⁽ⁱ⁼⁰⁾” is 0, which indicates that an initial state of the check node is 0. A symbol “∀” means any one, “∈” means belonging, and “∀n∈Nₘ” denotes any “n” belonging to “Nₘ.”

c_{m,n}⁽ⁱ⁼⁰⁾=0,∀m∈{1, . . . M},∀n∈Nₘ. Equation 1:

First step is to update the information of the variable node. In equation 2, the information (i.e., v2c information) that the variable node provides to the check node is updated, in which “N” is a quantity of the variable nodes, “M” is a quantity of the check nodes, “n” is a number of the variable node, and “m” is a number of the check node.

For n∈{1, . . . N} and m∈Mₙ;

v_{n,m}⁽ⁱ⁾=Iₙ+Σ_{m′∈M}_{_{n\m}}c_{m′,n}ⁱ⁻¹. Equation 2:

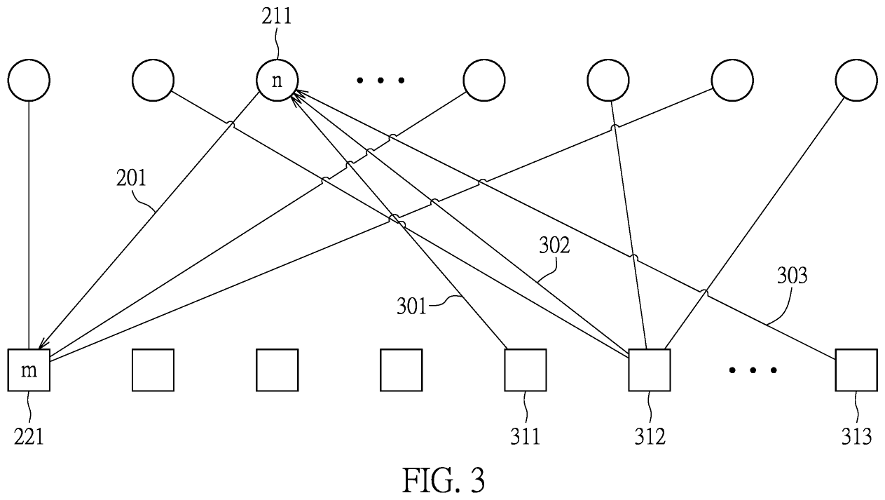

After the k^{th} iteration, “v_{n,m}^{(i=k)}” forms information that the variable node provides to the m^{th} check node. After excluding the connection to be calculated, a sum of the remaining connections among the variable nodes and the check nodes is calculated. The remaining connections are the variable nodes that participate in the m^{th} check equation. Reference is made to FIG. 3, which is an exemplary example depicting a Tanner graph used to illustrate a sum calculation during the LDPC decoding process. For example, to form the information (v_{n,m}^{(i=k)}) that the n^{th} variable node 211 provides to the m^{th} check node 221 after multiple iterations, the connection indicative of the v2c information 201 is excluded from the connections (301, 302 and 303) between the check nodes 311, 312 and 313 and the n^{th} variable node 211. A sum of the information transmitted between the check nodes 311, 312 and 313 and the n^{th} variable node 211 (i.e., the c2v information) and the intrinsic information (In) of the n^{th} variable node 211 need be obtained, so that the information of the variable node can be updated to “v_{n,m}⁽ⁱ⁾.”

Second step is to update information of the check node. In equation 3, the c2v information 201 that the m^{th} check node 221 provides to the n^{th} variable node 211 is updated. A sign function “sign( )” returns 0, 1 or −1 based on the value of the function is 0, a positive number or a negative number.

$$For m ∈ \{ 1 , … M \} and n ∈ {N}_{m} ; \\ {c}_{m , n}^{( i )} = α \cdot ( {\prod }_{{n}^{′} ∈ {N}_{m \backslash n}} sign ( {v}_{{n}^{′} , m}^{( i )} ) ) \cdot ( {min}_{{n}^{′} ∈ {N}_{m \backslash n}} ( \vert {v}_{{n}^{′} , m}^{( i )} \vert ) ) . \qquad Equation 3$$

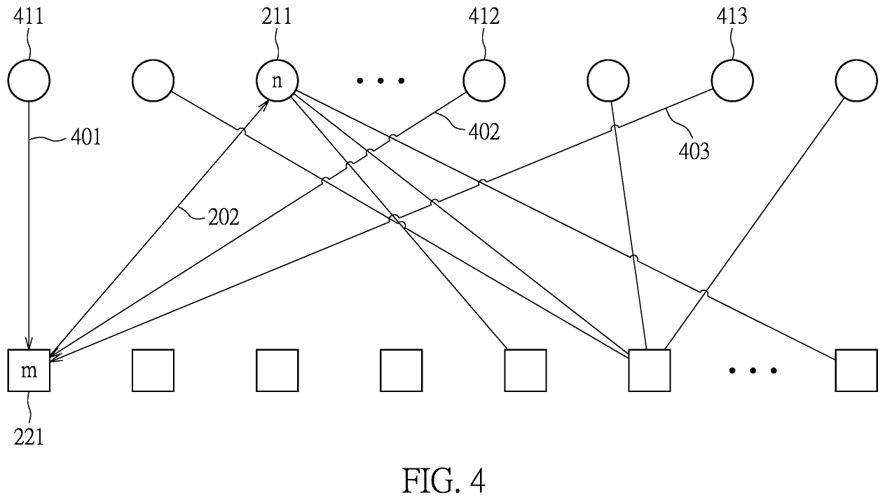

In the k^{th} iteration, “c_{m,n}^{(i=k)}”, forms information that the check node provides to the variable node. After excluding the connection to be calculated, a product among the remaining connections between the variable nodes and the check nodes is calculated. A minimum is obtained. Reference is made to FIG. 4, which shows a Tanner graph that is used to exemplarily illustrate a product calculation during the LDPC decoding process. Here, the information that the m^{th} check node 221 provides to the n^{th} variable node 211 is taken as an example. In the process of forming the information (c_{m,n}^{(i=k)}) that the check node provides to the variable node after multiple iterations, the connection indicative of c2v information 202 is excluded, and a product of the v2c information formed from the connections (401, 402 and 403) between the remaining variable nodes 411, 412 and 413 and the m^{th} check node 221 is calculated. A minimum “c_{m,n}⁽ⁱ⁾” is then obtained, and is used to update the c2v information that the m^{th} check node 221 provides to n^{th} variable node 211.

In a decision stage, the information obtained in the above steps can be summed up for making a final decision. For example, a hard decision algorithm is used to decode firstly. Each input signal and each output signal can be expressed as 1 or 0. In equation 4, the intrinsic information (In) of the variable node and the updated information that the check node provides to multiple variable nodes based on the connections between the check node and the other variable nodes are summed up as (Σ_{m′∈M}_{ₙ}c_{m′,n}ⁱ), so as to obtain the information (vₙ) of the variable node and make a final decision (Dₙ). Dₙ is 0 or 1.

$${v}_{n} = {I}_{n} + {\sum }_{{m}^{′} ∈ {M}_{n}} {c}_{{m}^{′} , n}^{i} {D}_{n} = \{ \begin{matrix}1 , & {v}_{n} < 0 \\ 0 , & {v}_{n} \geq 0\end{matrix} . \qquad Equation 4$$

In a next step, rather than the second step in the above initialization stage, a single-min algorithm min-sum algorithm (SMAMSA) is used in the initialization stage. The check node is updated as in equation 5.

In equation 5, the check node is updated. That is, the c2v information is updated. There are N variable nodes and M check nodes, in which “n” denotes a number of the variable node and “m” denotes a number of the check node.

$$For m ∈ \{ 1 , … M \} and n ∈ {N}_{m} ; \qquad Equation 5$$

$${c}_{m , n}^{( i )} = ( {\prod }_{{n}^{′} ∈ {N}_{m ∖ n}} sign ( {v}_{{n}^{′} , m}^{( i )} ) ) \cdot \{ \begin{matrix}min {1}^{est} , & when “ n ” of {c}_{m , n}^{i} is not “ n ” where minimum v 2 c is located ; \\ min {2}^{est} , & others ;\end{matrix}$$

$$min 1 = {min}_{{n}^{′} ∈ {N}_{m}} ( \vert {v}_{{n}^{′} , m}^{( i )} \vert ) ;$$

$$min {1}^{est} = α \cdot min 1 ;$$

$$min {2}^{est} = β \cdot min 1 + γ \cdot min {2}^{′′′} .$$

“c_{m,n}⁽ⁱ⁾” denotes the information that the check node provides to the variable node. “c_{m,n}⁽ⁱ⁾” in the SMAMSA is used to confirm an estimated first minimum (min1^{est}) or an estimated second minimum (min2^{est}). The estimated first minimum (min1^{est}) is used if the number (“n”) of the variable node in “c_{m,n}⁽ⁱ⁾” is not at a position of the minimum v2c information that the variable node provides to the check node; otherwise, the estimated second minimum (min2^{est}) is used. Accordingly, a dot product is performed between the estimated second minimum (min1^{est}) or the estimated second minimum (min2^{est}) and the updated variable node for updating information (c_{m,n}⁽ⁱ⁾) of the check node. “α” and “γ” are operational parameters in the equation for obtaining the estimated first minimum or the estimated second minimum.

In the above-mentioned single-min algorithm, in order to estimate the second minimum (min2, i.e., the second smallest value), the second minimum (min2, i.e., the second smallest value) originally used in the min-sum algorithm (MS) is substituted by the estimated second minimum (min2^{est}). The estimated second minimum is obtained from a false second minimum (min2′″) that can be obtained when searching for the first minimum (min1).

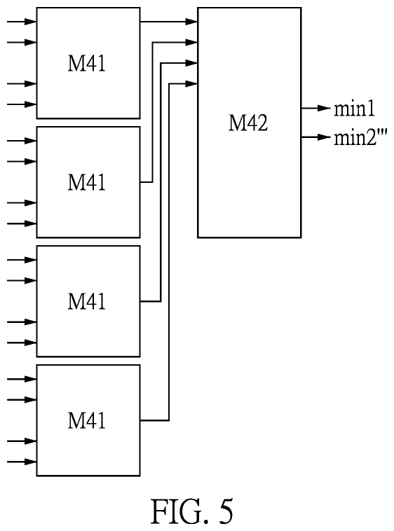

Any of the circuits depicted in FIG. 5 to FIG. 8 can be used to search for the first minimum (min1). However, the first minimum (min1) can also be obtained by other methods. In particular, apart from obtaining the first minimum by any of the circuits depicted in FIG. 5 to FIG. 8, additional information other than the first minimum can also be obtained. The additional information calculated from actual signals has a certain credibility, and can therefore be used to estimate the false second minimum (min2′″) of the second minimum. The false second minimum (min2′″) can still be obtained by the SMAMSA without any additional circuit. Accordingly, there is no need to use any additional hardware to obtain the second minimum (min2).

FIG. 5 to FIG. 8 show block diagrams of logic circuits whose check node degree is 16 according to certain embodiments of the present disclosure.

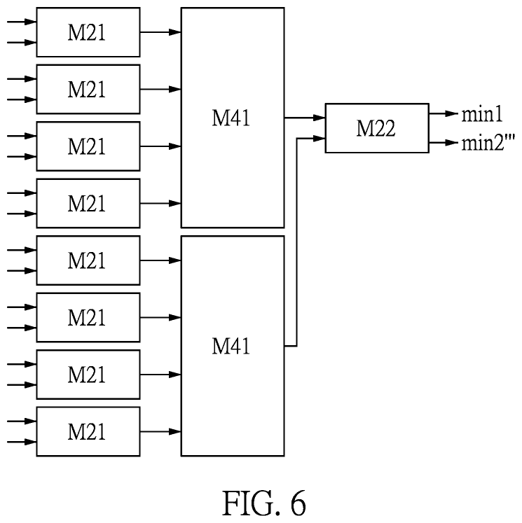

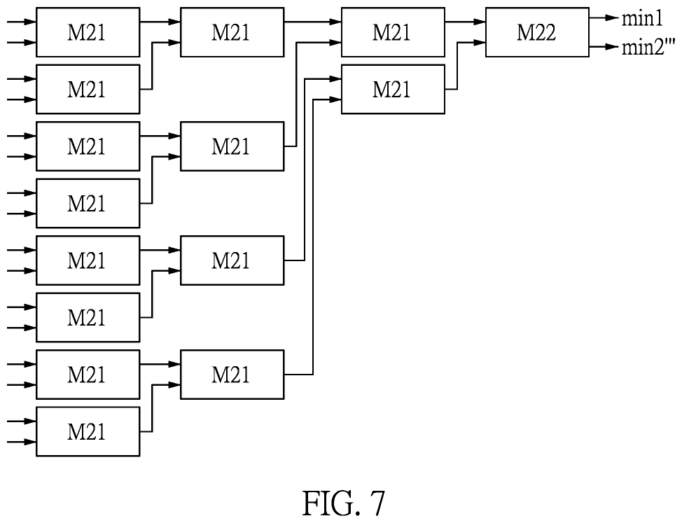

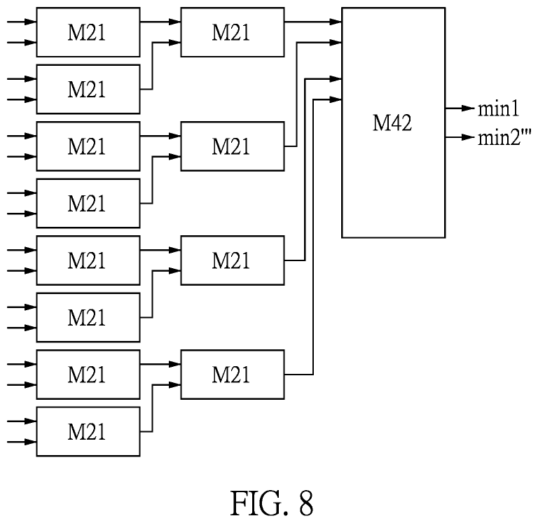

In FIG. 5, 16 input signals are shown to be inputted to 4 calculation units M41. After comparison operations, 4 minimums can be obtained from the 4 calculation units M41, and can then be inputted to a calculation unit M42. After the 4 minimums are compared, a first minimum (min1) can be obtained. It should be noted that a second minimum is not calculated, but a false second minimum (min2′″) is obtained from data accompanied with the first minimum. In FIG. 6, 16 input signals are shown to be inputted to 8 calculation units M21. Every 4 calculation units M21 generate a minimum that is configured to be inputted to next 2 calculation units M41. Afterwards, a next calculation unit M22 generates a first minimum (min1) and a false second minimum (min2′″). In FIG. 7, 16 input signals are shown to be correspondingly inputted to 8 calculation units M21. Every 2 calculation units M21 generate a minimum that is configured to be inputted to next 4 calculation units M21. Afterwards, the minimum obtained from the next 2 calculation units M21 is inputted to a calculation unit M22 for obtaining a first minimum (min1) and a false second minimum (min2′″) through a comparison operation. In FIG. 8, 16 input signals are shown to be correspondingly inputted to 8 calculation units M21. Every 2 calculation units M21 generate a minimum that is configured to be inputted to next 4 calculation units M21. Afterwards, a next calculation unit M42 generates a first minimum (min1) and a false second minimum (min2′″).

For example, when the check node degree is 16, a first degree of the 16 input signals is the v2c information that the n^{th} variable node (no. n) provides to the m^{th} check node (no. m). The v2c information can be expressed by “v_{n,m}⁽ⁱ⁾.” Afterwards, the first minimum (min1) is obtained, and the false second minimum (min2′″) can be obtained from data accompanied with the first minimum. The false second minimum (min2′″) can be the actual second minimum plus noises, i.e., the scrambled second minimum.

The decoding method and the decoding system of the present disclosure have improved the conventional SMAMSA, and an equation 6 for the estimated second minimum is provided. The equation 6 implements a modified SMAMSA (referred to as M-SMAMSA).

In equation 6, a function

$$“ {min}_{{n}^{′} ∈ {N}_{m}} ( ) ”$$

is used to obtain a minimum.

$$“ {min}_{{n}^{′} ∈ {N}_{m}} ( \vert {v}_{{n}^{′} , m}^{( i )} \vert ) ”$$

is used to obtain a minimum of “v_{n′,m}⁽ⁱ⁾” (that is, the information that the variable node provides to the check node with exclusion of the connection to be calculated). The estimated first minimum and the estimated second minimum can be obtained. Based on the information (v_{n′,m}⁽ⁱ⁾) and with exclusion of the connection to be calculated, a product among the other connections (n′) between the variable nodes and the check nodes is calculated. It should be noted that the equation 6 estimates the information of a node based on the adjacent connections. After a dot product between the information and the estimated first minimum or the estimated second minimum is calculated, the information (c_{m,n}⁽ⁱ⁾) that the check node provides to the variable node can be obtained.

$$For m ∈ \{ 1 , … M \} and n ∈ {N}_{m} ; \qquad Equation 6$$

$${c}_{m , n}^{( i )} = ( {\prod }_{{n}^{′} ∈ {N}_{m ∖ n}} sign ( {v}_{{n}^{′} , m}^{( i )} ) ) \cdot \{ \begin{matrix}min {1}^{est} , & when “ n ” of {c}_{m , n}^{i} is not “ n ” where minimum v 2 c is located ; \\ min {2}^{est} , & others ;\end{matrix}$$

$$min 1 = {min}_{{n}^{′} ∈ {N}_{m}} ( \vert {v}_{{n}^{′} , m}^{( i )} \vert ) ;$$

$$min {1}^{est} = α \cdot min 1 ;$$

$$min {2}^{est} = β \cdot min 1 + γ \cdot min {2}^{′′′} .$$

Compared to the conventional SMAMSA, the estimated first minimum (min1^{est}) obtained from the modified SMAMSA of equation 6 is consistent with the first minimum obtained in equation 5 before the modification. “α”, “γ” and “β” are weights in the equation 6. When the modified SMAMSA is used to estimate the estimated second minimum (min2^{est}), the first minimum (min1) is multiplied by “α” (a first parameter), the false second minimum (min2′″) is multiplied by “γ” (a third parameter), and the first minimum (min1) is multiplied by “β (a second parameter).

Accordingly, the modified SMAMSA changes dimensions for generating the estimated second minimum (min2^{est}). For example, two dimensions in the original SMAMSA (e.g., in equation 5) are changed to three dimensions (e.g., in equation 6). Therefore, the modified SMAMSA is able to increase a range of use, so as to cooperate with more modulations and have a wider range of fixed points of the decoder. In the present disclosure, the modified SMAMSA is also required to comply with the following rules when adding the parameters “α”, “β” and “γ” to the equation 6.

min2^{est}≥min1^{est}.

min2′″≥min1.

Accordingly, the minimum of min2′″ is equal to min1. In addition, if min2′″=min1 and “min2^{est}” is at lower bound, a relationship: min2^{est}=(β+γ)·min1≥min1^{est}=α·min1 can be derived. Therefore, the parameters “α”, “β” and “γ” comply with a relationship of “(β+γ)≥α”.

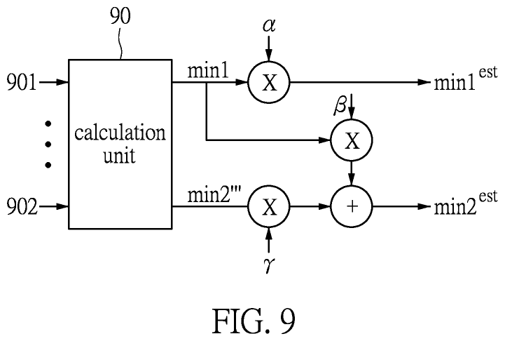

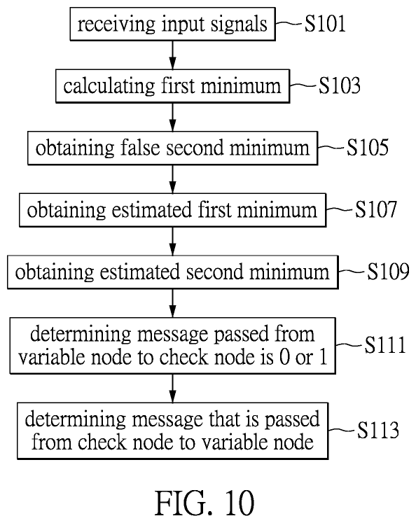

Reference is made to FIG. 9, which is a block diagram of logic circuits that implement the modified SMAMSA according to one embodiment of the present disclosure. FIG. 10 is a flow chart describing the decoding method adopting an algorithm with weight-based adjusted parameters according to one embodiment of the present disclosure.

In FIG. 10, after a decoder receives signals, M×N low density parity check codes including N variable nodes and M check nodes are generated and expressed by input signals 901 and 902 (step S101). The input signals are, for example, the information (v_{n′,m}⁽ⁱ⁾) that the multiple variable nodes provide to the check nodes. To update the information of the check nodes, via a calculation unit 90 (references are made to FIG. 5 to FIG. 8), equation 6 is used to calculate a first minimum (min1) (step S103). The data accompanied with the first minimum can be used to obtain a false second minimum (min2′″) (step S105).

In equation 6, in compliance with the relationship of (β+γ)≥α, the first minimum is multiplied by a first parameter (α) for obtaining an estimated first minimum (min1^{est}) (step S107). An estimated second minimum (min2^{est}) is obtained by the first minimum being multiplied by a second parameter (β) plus the false second minimum being multiplied by a third parameter (γ) (step S109). In the meantime, based on the information that the variable nodes provide to the check nodes, after excluding the connection to be calculated, a sum of the remaining connections is calculated for determining a value 0 or 1 (v_{n′,m}⁽ⁱ⁾) (step S111). Afterwards, whether or not the value “n” (a number of the variable node) of “c_{m,n}⁽ⁱ⁾” is at the connection with the minimum (v_{n,m}⁽ⁱ⁾) that the n^{th} variable node provides to m^{th} check node is determined, so as to determine if the estimated first minimum (min1^{est}) is to be used. On the contrary, the estimated second minimum (min2^{est}) is used if the value “n” of “c_{m,n}⁽ⁱ⁾” is not at the connection with the minimum (v_{n,m}⁽ⁱ⁾) that the n^{th} variable node provides to m^{th} check node. The result (0 or 1) in step S111 is used to perform a dot product, so as to obtain the information (c_{m,n}⁽ⁱ⁾) that the check nodes provide to the variable nodes (step S113).

Furthermore, in the decoding method, a pre-processing process can be performed before the signals are inputted to the decoder. In the pre-processing process, in view of hardware limitation, a decode-scaling method can be performed to adjust the signals, such that the decoder is able to identify the features of the signals. Decode scaling can be determined by comparing a noise-power ratio with a threshold set by the decoding system. The decode-scaling method can improve a bandwidth limitation caused by the fixed points of the decoder, thereby solving a problem of reduced performance due to the bandwidth limitation.

For example, for the LLR entering the LDPC decoder, the decode-scaling method is used to adjust a weight of the LLR inputted to the decoder since the information of an inverse of noise power (1/σ²) is required by the decoder when performing an LLR calculation. It should be noted that the inverse of noise power (1/σ²) provides information of a signal-noise ratio (SNR), and the inverse of noise power (1/σ²) can be used to adjust the strength of signals in each channel. Therefore, a correct LLR is provided to the decoder.

In a practical application, the signal-noise ratio operated in the decoding system may cross an 8-9 dB interval, such that a dynamic range of the inverse of noise power required when the LLR is inputted to the LDPC decoder falls in a range of 2 to 8. To completely cover the whole dynamic range, the fixed points of the decoder should increase a bit width for maintaining the performance of the decoder. However, the additional bit width may increase hardware area and power consumption. Accordingly, the decode-scaling method for the LLR is provided for suppressing changes such as the bit width of the fixed points.

In summation, according to the above embodiments of the decoding method adopting an algorithm with weight-based adjusted parameters and the decoding system, the modified SMAMSA that is a new single-sum framework with a layered decoding technology is provided. Compared with the conventional algorithms, the modified SMAMSA provides variables with more dimensions, and the range of application is expanded. Better performance than the conventional NMS is also provided. Further, the modified SMAMSA provides a lower error rate when the single minimum is used with the scrambled second minimum. Since only the first minimum is searched for, the modified SMAMSA can reduce hardware complexity and power consumption. At an input signal end, the decoding method uses various decode-scaling methods for different signal-noise ratios, and therefore provides optimized performance since the hardware area is reduced for the reduced bit width.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A decoding method adopting an algorithm with weight-based adjusted parameters, wherein the decoding method is applied to a decoder having “N” variable nodes and “M” check nodes, in which input signals generate “M*N” low density parity check codes, and the decoding method comprises:
initializing information of the variable nodes and the check nodes;
updating the variable nodes, wherein each of the variable nodes is updated based on the information of the check nodes connected thereto, and wherein the information that each of the variable nodes provides to the check nodes is formed by multiple iterations, and a sum of connections among the variable nodes and the check nodes is calculated after excluding the connections to be calculated; and
updating the check nodes, wherein each of the check nodes is updated according to the information of the variable nodes connected thereto, wherein the information that each of the check nodes provides to the variable nodes is formed by the multiple iterations, a product of connections among the variable nodes and the check nodes is calculated after excluding the connections to be calculated, and a dot product is then calculated according to an estimated first minimum or an estimated second minimum, so as to obtain the information that the check nodes provide to the variable nodes for making a decision, and wherein:
searching for a minimum of the updated variable nodes, so as to obtain a first minimum;
obtaining a false second minimum from data accompanied with the first minimum;
multiplying the first minimum by a first parameter (α) for obtaining the estimated first minimum; and
multiplying the first minimum by a second parameter (β) and adding a result of the false second minimum multiplied by a third parameter (γ), so as obtain the estimated second minimum.

2. The decoding method according to claim 1, wherein the first parameter (α), the second parameter (β) and the third parameter (γ) satisfy a relation expressed by (β+γ)≥α.

3. The decoding method according to claim 1, wherein, in the step of initializing the information of the variable nodes and the check nodes, intrinsic information is one-by-one written into the multiple variable nodes before the iterations are performed.

4. The decoding method according to claim 1, wherein the estimated first minimum or the estimated second minimum is determined according to a determination result of whether or not a number of the variable node in the information that the check node provides to the variable node is a position of the information that the smallest variable node provides to the check node.

5. The decoding method according to claim 4, wherein the first parameter (α), the second parameter (β) and the third parameter (γ) satisfy a relational expression (β+γ)≥α.

6. The decoding method according to claim 1, wherein intrinsic information of the variable node is summed up with the information that the check node provides to the multiple variable nodes and is updated via a connection between the check node and the other variable nodes, so as to obtain the information of the variable node for making the decision.

7. The decoding method according to claim 6, wherein the first parameter (α), the second parameter (β) and the third parameter (γ) satisfy a relational expression (β+γ)≥α.

8. The decoding method according to claim 1, wherein, in a pre-processing step of the decoder, a decode scaling method is used to control a log-likelihood ratio for adjusting a weight value that is inputted to the log-likelihood ratio.

9. The decoding method according to claim 8, wherein the first parameter (α), the second parameter (β) and the third parameter (γ) satisfy a relational expression (β+γ)≥α.

10. The decoding method according to claim 9, wherein an equation for obtaining the information that the check node provides to the variable node is as follows:
$$for m ∈ \{ 1 , … M \} and n ∈ {N}_{m} ;$$
$${c}_{m , n}^{( i )} = ( {\prod }_{{n}^{′} ∈ {N}_{m ∖ n}} sign ( {v}_{{n}^{′} , m}^{( i )} ) ) \cdot \{ \begin{matrix}min {1}^{est} , & when “ n ” of {c}_{m , n}^{i} is not “ n ” where minimum v 2 c is located ; \\ min {2}^{est} , & others ;\end{matrix}$$
$$min 1 = {min}_{{n}^{′} ∈ {N}_{m}} ( \vert {v}_{{n}^{′} , m}^{( i )} \vert ) ;$$
$$min {1}^{est} = α \cdot min 1 ;$$
$$min {2}^{est} = β \cdot min 1 + γ \cdot min {2}^{′′′} .$$
wherein “N” denotes number of the variable node; “M” denotes number of the check node; “c_{m,n}⁽ⁱ⁾” denotes information that the m-numbered check node sends to the n-numbered variable node; “n′” denotes a number of the remaining variable node(s) with exclusion of the connection to be calculated; “v_{n′,m}⁽ⁱ⁾” denotes information that the n′-numbered variable node(s) sends to the m-numbered check node after excluding the connection to be calculated, and is v2c information; a sign function “sign( )” is used to return to a value “0”, “1” or “−1” according to the value “0”, “a positive number” or “a negative number” in the sign function; “min1” is the first minimum;
$$“ {min}_{{n}^{′} ∈ {N}_{m}} ( \vert {v}_{{n}^{′} , m}^{( i )} \vert ) ”$$
is a function used to acquire minimum; “min1^{est}” is the estimated first minimum; “min2^{est}” is the estimated second minimum; and “min2′″” denotes the false second minimum.

11. A decoding system, comprising a decoder disposed at a receiving end of the decoding system, in which a decoding method adopting an algorithm with weight-based adjusted parameters is performed according to steps as follows:
generating M*N low density parity check codes having N variable nodes and M check nodes from input signals;
initializing information of the variable nodes and the check nodes;
updating the variable nodes, wherein each of the variable nodes is updated based on the information of the check nodes connected thereto, and wherein the information that each of the variable nodes provides to the check nodes is formed by multiple iterations, and a sum of connections among the variable nodes and the check nodes is calculated after excluding the connections to be calculated; and
updating the check nodes, wherein each of the check nodes is updated according to the information of the variable nodes connected thereto, wherein the information that each of the check nodes provides to the variable nodes is formed by the multiple iterations, a product of connections among the variable nodes and the check nodes is calculated after excluding the connections to be calculated, and a dot product is then calculated according to an estimated first minimum or an estimated second minimum so as to obtain the information that the check nodes provide to the variable nodes for making a decision, and wherein:
searching for a minimum of the updated variable nodes so as to obtain a first minimum;
obtaining a false second minimum from data accompanied with the first minimum;
multiplying the first minimum by a first parameter (α) for obtaining the estimated first minimum; and
multiplying the first minimum by a second parameter (β) and adding a result of the false second minimum multiplied by a third parameter (γ) so as obtain the estimated second minimum.

12. The decoding system according to claim 11, wherein the first parameter (α), the second parameter (β) and the third parameter (γ) satisfy a relational expression (β+γ)≥α.

13. The decoding system according to claim 11, wherein, in the step of initializing the information of the variable nodes and the check nodes, intrinsic information is one-by-one written into the multiple variable nodes before the iterations are performed.

14. The decoding system according to claim 11, wherein the estimated first minimum or the estimated second minimum is determined according to a determination result of whether or not a number of the variable node in the information that the check node provides to the variable node is a position of the information that the smallest variable node provides to the check node.

15. The decoding system according to claim 14, wherein the first parameter (α), the second parameter (β) and the third parameter (γ) satisfy a relational expression (β+γ)≥α.

16. The decoding system according to claim 10, wherein intrinsic information of the variable node is summed up with the information that the check node provides to the multiple variable nodes and is updated via a connection between the check node and the other variable nodes so as to obtain the information of the variable node for making the decision.

17. The decoding system according to claim 16, wherein the first parameter (α), the second parameter (β) and the third parameter (γ) satisfy a relational expression (β+γ)≥α.

18. The decoding system according to claim 11, wherein, in a pre-processing step of the decoder, a decode scaling method is used to control a log-likelihood ratio for adjusting a weight value that is inputted to the log-likelihood ratio.

19. The decoding system according to claim 18, wherein the first parameter (α), the second parameter (β) and the third parameter (γ) satisfy a relational expression (β+γ)≥α.

20. The decoding system according to claim 19, wherein an equation for obtaining the information that the check node provides to the variable node is as follows:
$$for m ∈ \{ 1 , … M \} and n ∈ {N}_{m} ;$$
$${c}_{m , n}^{( i )} = ( {\prod }_{{n}^{′} ∈ {N}_{m ∖ n}} sign ( {v}_{{n}^{′} , m}^{( i )} ) ) \cdot \{ \begin{matrix}min {1}^{est} , & when “ n ” of {c}_{m , n}^{i} is not “ n ” where minimum v 2 c is located ; \\ min {2}^{est} , & others ;\end{matrix}$$
$$min 1 = {min}_{{n}^{′} ∈ {N}_{m}} ( \vert {v}_{{n}^{′} , m}^{( i )} \vert ) ;$$
$$min {1}^{est} = α \cdot min 1 ;$$
$$min {2}^{est} = β \cdot min 1 + γ \cdot min {2}^{′′′} .$$
wherein, “N” denotes number of the variable nodes; “M” denotes number of the check nodes; “c_{m,n}⁽ⁱ⁾” denotes information that the m-numbered check node sends to the n-numbered variable node; “n′” denotes a number of the remaining variable node(s) with exclusion of the connection to be calculated; “v_{n′,m}⁽ⁱ⁾” denotes information that the n′-numbered variable node(s) sends to the m-numbered check node after excluding the connection to be calculated, and is v2c information; a sign function “sign( )” is used to return to a value “0”, “1” or “−1” according to the value “0”, “a positive number” or “a negative number” in the sign function; “min1” is the first minimum;
$$“ {min}_{{n}^{′} ∈ {N}_{m}} ( \vert {v}_{{n}^{′} , m}^{( i )} \vert ) ”$$
is a function used to acquire a minimum; “min1^{est}” is the estimated first minimum; “min2^{est}” is the estimated second minimum; and “min2′″” denotes the false second minimum.
